(19) United States
(12) Patent Application Publication
(10) Pub. No.: US 2026/0221938 A1
(43) Pub. Date: Jul. 30, 2026

(54) OSCILLATOR AND TRANSCEIVER COMPRISING THIS OSCILLATOR

(71) Applicant: CSEM CENTRE SUSSIE D'ELECTRONIQUE ET DE MICROTECHNIQUE SA - RECHERCHE ET DÉVELOPPEMENT, Neuchâtel (CH)

(72) Inventor: Konstantinos MANETAKIS, Neuchâtel (CH)

(21) Appl. No.: 19/099,611

(22) PCT Filed: Jul. 21, 2023
(86) PCT No.: PCT/IB2023/057462

§ 371 Date: Jan. 29, 2025

(30) Foreign Application Priority Data
Aug. 3, 2022 (EP) 22188429.9

(51) Int. Cl. H03B 5/12; H03F 3/24; H03L 7/099

(52) U.S. Cl. CPC H03B 5/1212; H03F 3/245; H03L 7/099; H03F 2200/294

(57) ABSTRACT

An oscillator (100) is arranged to output a differential voltage oscillator carrier. The oscillator has a tank circuit (20, 30), and an active circuit (10) connected to the tank circuit (20, 30). The active circuit (10) includes a crossed coupled pair of transistors (T1, T2), each transistor having a terminal (B1, B2), said terminal (B1, B2) allowing to modify a threshold voltage of the transistor (T1, T2). The oscillator (100) also has a control circuit arranged to modify the voltage at the fourth terminal (B1, B2) of at least a subset of the transistors (T1, T2), so as to minimize a phase difference between the differential voltage oscillator carrier and a device current of the active circuit (10), the device current (i_{D}) of the active circuit (10) being a drain current flowing in one of the transistors (T1, T2), thereby minimizing low frequency noise to phase noise conversion.

### TECHNICAL DOMAIN

The present invention concerns an oscillator. The present invention concerns also a transceiver comprising this oscillator.

### RELATED ART

An oscillator is in general used to generate a carrier signal, having a carrier frequency. In general, this carrier frequency is an RF frequency, i.e. a frequency between 3 kHz and 300 GHz, in particular between 300 MHz and 100 GHz.

An oscillator in general comprises:
a tank circuit, and
an active circuit (or active device) connected to the tank circuit, the active circuit comprising transistors.

The tank circuit provides a resonant frequency. In general, the tank circuit comprises an inductor and a capacitor, and the oscillator is named “LC-tuned oscillator”. It can comprise a common mode part and a differential part and then a differential respectively common-mode tank impedance.

The active circuit allows to sustain the oscillation of the tank circuit. It can be modelled as a nonlinear transconductor G (V):

$$G ( V ) = {g}_{1} V + {g}_{2} {V}^{2} + {g}_{3} {V}^{3} \qquad ( 1 )$$

wherein
V is the differential voltage across the active circuit, which in general corresponds to the differential voltage across the tank circuit and constitutes the differential voltage oscillator carrier V=A sin(ω₀ t) where A is the oscillator voltage amplitude, wo is the oscillator carrier frequency and t is the time
g₁ is the first-order transconductance of the active circuit as a whole
g₂ is the second-order transconductance of the active circuit as a whole
g₃ is the third-order transconductance of the active circuit as a whole.

Low frequency noise is present within the oscillator. In this context the expression “low frequency noise” indicates a noise having a frequency lower than the carrier frequency, e.g. a frequency lower than 100 MHz, in particular between 10 Hz and 100 MHz.

This low frequency noise can comprise 1/f noise (or flicker noise) inherent in the active circuit, low frequency noise emanating from the oscillator voltage and/or bias circuitry of the active circuit.

Non-linear operation of components within the oscillator can up-convert noise present within the oscillator. The up-converted noise can produce phase noise in the differential voltage oscillator carrier signal, and noise side bands on either side of the oscillator carrier worsening the oscillator spectral purity and resulting in deteriorated phase noise performance.

In modern submicron processes, low frequency noise to phase noise up-conversion is detrimental, as the low frequency noise corner extends well into the MHz range, thus affecting phase noise up to several MHz from the carrier.

Low-frequency noise to phase noise up-conversion comprises in general two steps.

The first step is the up-conversion of low-frequency noise to the carrier frequency due to the cyclo-stationary nature of the oscillator operation. This is unavoidable if the oscillator active circuit operates under large-signal conditions. The operating region of the active devices in fact varies continuously over the oscillator period. They operate in saturation, triode and cut-off. Their noise density depends on their terminal voltages and currents. As these vary over the oscillator period, so do the statistics of their noise density.

The second step is the conversion of the up-converted low-frequency noise to phase noise. This step is governed by the following phase dynamics equation:

$$\frac{d θ}{dt} = {ω}_{0} + \frac{{i}_{n}}{A C} cos ( {ω}_{0} t ) \qquad ( 2 )$$

wherein:
θ is the oscillator phase
t is the time
ω₀ is the carrier frequency
A is the oscillator carrier (voltage) amplitude
C is the tank capacitance
iₙ is the injected noise current.

From the phase dynamics equation (1), it can be shown that the phase noise PN due to transconductor 1/f noise, as well as, due to low-frequency supply/bias noise is given by:

$$P N ∼ \frac{sin ϕ}{{C}^{2} {{A}^{2} ( Δ ω )}^{3}} \qquad ( 3 )$$

Wherein:
φ is phase shift between the first harmonic of the differential voltage oscillator carrier and the transconductor first harmonic current
Δω is the frequency offset from the oscillator carrier frequency ω₀.

The phase shift φ between the first harmonic of the differential voltage oscillator carrier and the first harmonic transconductance current is given by

$$ϕ = {tan}^{- 1} ( - \frac{{( {g}_{1} R - 1 )}^{2}}{8 Q} ) \qquad ( 4 )$$

wherein:
R is the tank parallel loss resistance
Q is the tank quality factor.

For the oscillator to start up, the product (g₁·R) should be higher than one, therefore φ attains a small value, resulting in finite low-frequency noise to phase noise conversion.

Considering common-mode effects, the phase shift φ becomes

$$ϕ = {tan}^{- 1} ( - \frac{{( {g}_{1} R - 1 )}^{2}}{8 Q} + \frac{2 {g}_{2}}{3 {g}_{3}} ( {g}_{1} R - 1 ) {Z}_{CMi} ( 2 {ω}_{0} ) ) \qquad ( 5 )$$

wherein:
Z_{CMi}(2ω₀) is the imaginary part of the tank common-mode impedance Z_{CM} at the oscillator second harmonic 2ω₀.

Document U.S. Pat. No. 9,559,702B1 indicates that by properly designing the term Z_{CMi}(2ω₀), it is possible that φ attains a small value or a null value, thereby reducing the conversion of low-frequency noise to phase noise.

In practice, however, it is very difficult to predict and thus accurately design the value of the common-mode tank impedance, because the common-mode tank impedance is usually distributed, making its accurate simulation difficult.

Moreover, the possibilities to reduce the low-frequency noise to phase noise conversion after the fabrication of the oscillator are low or null.

The document US2020228060 divulgates a class-C oscillator topology and indicates that the back-gate bias control of the oscillator results in lower phase noise, as the oscillation amplitude can be larger than in traditional class-C oscillators. Biasing the back-gate improves phase noise by virtue of increasing the oscillator amplitude.

The document US20170257063 describes another class-C oscillator topology. The fourth terminal is controlled for regulating the oscillator bias and getting a good trade-off between phase noise and power consumption. An automatic bias control method maintains large bias during startup, then reduces the bias when the oscillator has started.

The document EP2079162 describes different techniques for signal processing having reduced flicker noise, by using transistors having a switched bias and receiving a forward body-bias as well. The forward body-bias signal may be constant or switched.

The document U.S. Pat. No. 10,942,255 concerns an apparatus for a wireless receiver, which integrates an injection-locked buffer and an oscillator for conducting a Built-In Self Test (BIST) into a single region of an integrated circuit (IC) chip. Back-gate region of the transistors can be set to a predetermined voltage bias to allow the transistors of an oscillator to produce testing signals in scenarios where no reference signal is transmitted through the corresponding injection-locked buffer.

### SHORT DISCLOSURE OF THE INVENTION

An aim of the present invention is the provision of an oscillator that overcomes the shortcomings and limitations of the state of the art.

Another aim of the invention is provision of an oscillator wherein the conversion of low-frequency noise to phase noise is reduced in a way alternative to the known solutions.

Another aim of the invention is provision of an oscillator wherein the conversion of low-frequency noise to phase noise can be at least partially reduced also after the fabrication of the oscillator.

According to the invention, these aims are attained by the object of the attached claims, and especially by an oscillator arranged to generate a differential voltage oscillator carrier, the oscillator comprising:
a tank circuit,
an active circuit connected to the tank circuit, the active circuit comprising a crossed coupled pair of transistors, each transistor comprising a terminal, this terminal allowing to modify a threshold voltage of the transistor.

According to the invention, the oscillator comprises also a control circuit arranged to modify the voltage at the fourth terminal of at least a sub-set of those transistors, so as to minimize a phase difference between a differential voltage of the oscillator carrier and a device current of the active circuit, the device current of the active circuit being a drain current flowing in one of the transistors, thereby minimizing low frequency noise to phase noise conversion.

In this context, the expression “drain current” designates the current flowing at the drain terminal of the corresponding transistor. In this context, the drain current is a signal current. In this context, the drain current is a differential current.

According to the invention, the fourth terminal allows to modify a threshold voltage of at least a sub-set of the transistors of the active circuit. In one embodiment, the fourth terminal is the bulk terminal of those transistors. In another embodiment, in particular if the transistors are realised in the technology silicon on insulator (SIO) or fully depleted silicon on insulator (FDSOI), the fourth terminal is the back gate terminal of the transistors. In another embodiment in which the transistors comprise two gate terminals, the fourth terminal is one of the two gate terminals.

With respect to what is known in the art, the conversion of low-frequency noise to phase noise is reduced in a way which is alternative to the known solutions.

In fact, the applicant has discovered that, it is possible to modify the value of the second-order transconductance g₂ in formula (5), by modifying the voltage at the fourth terminal of at least a sub-set of those transistors. This allows to reduce φ to small values or to a null value, thereby reducing the conversion of low-frequency noise to phase noise.

Advantageously, the modification of the value of the second-order transconductance g₂ does not change the amplitude of the generated differential voltage oscillator carrier. On the contrary, the modification of the value of the first-order transconductance g₁ or of the value of the third-order transconductance g₃ affects the amplitude of the generated differential voltage oscillator carrier.

Therefore, according to the invention it is possible to reduce φ to small values or to a null value, thereby reducing the conversion of low-frequency noise to phase noise, without affecting the amplitude of the generated differential voltage oscillator carrier.

Thanks to the applicant's discovery, it is possible to perform a control of the term g₂ in formula (5), without having to accurately predict the value of the tank common-mode impedance at the oscillator second harmonic Z_{CMi}(2ω₀).

Most importantly, this control can be performed even post fabrication, without modifying the hardware of the oscillator according to the invention. In fact, this modification can be implemented by an algorithm executed by the control circuit of the oscillator according to the invention.

The skilled person, facing the problems mentioned above, would not be incited to modify the voltage at the fourth terminal of at least a sub-set of the transistors of the active circuit, in order to reduce the conversion of low-frequency noise to phase noise, for a number of reasons. First, the skilled person does not know that there exists a relation between the value of the second-order transconductance g₂ and the voltage at the fourth terminal of at least a sub-set of the transistors of the active circuit. Second, the skilled person is not incited to modify the voltage at the fourth terminal of those transistors, as this changes the threshold voltage of those transistors, which in general is not desirable. Third, in general it is recommended to connect the fourth terminal to the source terminal, thereby avoiding its control. In fact, between the source terminal and the bulk terminal (as well as between the drain terminal and the bulk terminal) there is a diode and it is desirable that it is not forwarded biased, for avoiding the conduction of an unwanted current.

In one embodiment, the control circuit is arranged to modify the voltage at the fourth terminal of all the transistors of the active circuit.

In one embodiment, at least the sub-set of the transistors of the active circuit, and preferably all the transistors of the active circuit, is (are) realised in the technology fully depleted silicon on insulator (FDSOI) or in the technology deeply depleted channel (DDC).

In one embodiment, the control circuit comprises (at least one) digital to analog converter (DAC) whose output is connected to each fourth terminal of at least the sub-set of the transistors of the active circuit, and a decoupling capacitor between the DAC's output and ground. This embodiment allows to carefully control the voltage at each fourth terminal of at least the sub-set of the transistors of the active circuit, by shunting the extra-noise to ground thanks to the decoupling capacitor, thereby avoiding to affect the working of the transistors.

In one embodiment, the tank circuit comprises a common mode part and a differential part.

In one embodiment, the common mode part is modeled as a common inductor between a supply node and a common node, and a common capacitor between the common node and the ground.

In one embodiment, the differential part comprises an inductor, a capacitor and a resistor, the inductor, the capacitor and the resistor being in parallel. In one embodiment, this resistor models the differential tank loss.

In one embodiment, the oscillator is a voltage-biased oscillator.

In one embodiment, the oscillator is a current-biased oscillator.

The present invention concerns also a transceiver comprising:
a transmitting path, comprising the oscillator according to the invention,
a receiving path.

In one embodiment, the transceiver is a radio-frequency (RF) transceiver.

In this context the term “RF” or the expression “radio-frequency” indicates a range of frequencies between 3 kHz and 300 GHZ, in particular between 300 MHz and 100 GHz.

RF transceivers are well known and widely used, in communication devices (e.g., in portable or wearable devices), to perform signal transmission and reception over one or multiple frequency bands according to communication standards, as for example Bluetooth (BT), Bluetooth Low Energy (BLE), WCDMA, CDMA, GSM, LTE standards for cellular telephony, IEEE 802.11 protocols for wireless LAN, etc.

In one embodiment, the transceiver comprises a single (RF) antenna port common to the transmitting path and the receiving path. The presence of a single (RF) antenna port common is not essential and the transceiver could comprise instead two (or more) antenna ports.

In one embodiment,
the transmitting path comprises:
   a phase-locked loop, the oscillator being connected to the output of the phase-locked loop, the output of the oscillator being an input of the phase-locked loop,
   a divider, arranged to divide the frequency of the differential voltage oscillator carrier by a number, and being connected to the output of the oscillator,
   a power amplifier, connected to an output of the divider,
the receiving path comprises:
   a low noise amplifier,
   two mixers, each mixer being connected to the output of the low noise amplifier, one of the mixer being connected to a first output of the divider, and the other mixer being connected to a second output of the divider
   an analog and digital base-band circuit, connected to the output of each mixer,
a switch connecting the output of the power amplifier to the input of the low noise amplifier,
   the transceiver comprises a transceiver control circuit, arranged to:
close said switch, thereby creating a loopback path between the transmitting path and the receiving path,
inject a low-frequency tone at a supply of said oscillator, thereby generating up-converted tones around the differential voltage oscillator carrier,
recover at the digital base-band circuit the amplitude of the up-converted tones
sweep the voltage at the fourth terminal of the active circuit transistors, so as to minimize the amplitude of the up-converted tones, thereby calibrating the oscillator to reduce the low-frequency to phase-noise conversion.

This embodiment allows to calibrate the oscillator to reduce the low-frequency to phase-noise conversion without adding or using new components to the transceiver, but by implementing a specific algorithm by transceiver control circuit.

In one embodiment, the transceiver control circuit is arranged to perform those steps at a start-up phase of the transceiver.

### SHORT DESCRIPTION OF THE DRAWINGS

Exemplar embodiments of the invention are disclosed in the description and illustrated by the drawings in which:

FIG. 1 illustrates schematically an oscillator according to an embodiment of the invention.

FIG. 2 illustrates schematically an oscillator according to another embodiment of the invention.

FIG. 3 illustrates schematically a portion of the oscillator according to another embodiment the invention.

FIG. 4 illustrates schematically a transceiver comprising an oscillator according to an embodiment of the invention.

### EXAMPLES OF EMBODIMENTS OF THE PRESENT INVENTION

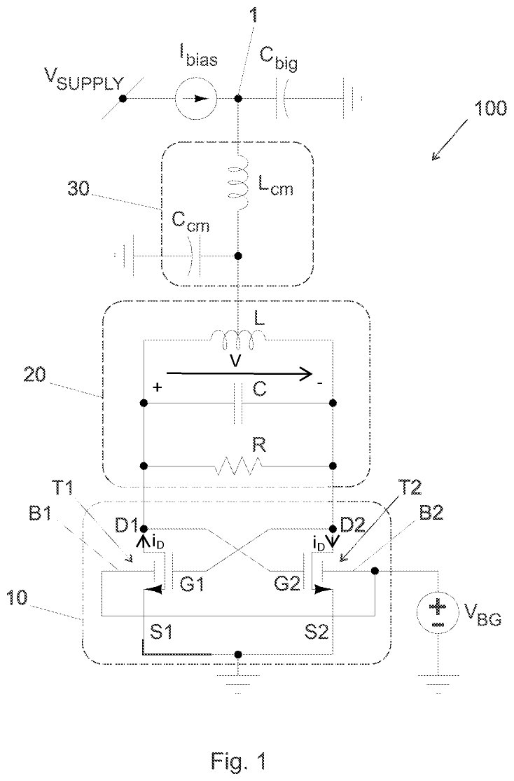

FIG. 1 illustrates schematically an oscillator 100 according to an embodiment of the invention. The oscillator 100 is a current-biased oscillator. It comprises:
a tank circuit, comprising a common mode part 30 and a differential part 20, and
an active circuit 10 connected to the tank circuit, the active circuit comprising a crossed coupled pair of transistors T1 and T2.

The common mode part 30 of the tank circuit is modeled as a common-mode inductor Lom between a supply node and a common node 1, and a common-mode capacitor C_{cm} between the common node and the ground.

The differential part 20 of the tank circuit comprises a (differential mode) inductor L, a (differential mode) capacitor C and a (differential mode) resistor R modelling differential tank losses. The inductor L, the capacitor C and the resistor R are in parallel.

The active circuit 10 of FIG. 1 comprises a crossed coupled pair of transistors T1 and T2. Each transistor T1, T2 comprises four terminals, i.e.:
a first terminal,
a second terminal,
a third terminal, and
a fourth terminal.

In the context of the present invention, the term “terminal” must be considered as a synonym of a node. It does not necessarily indicate that it is a pin that can be physically accessed by a user.

In one embodiment, the first terminal is the drain terminal, the second terminal is a gate terminal, and the third terminal is the source terminal of the transistor. According to the invention, the fourth terminal allows to modify a threshold voltage of the transistor. Then, in one embodiment, the fourth terminal is the bulk terminal of the transistor. In another embodiment, in particular if the transistor is realised in the technology silicon on insulator (SIO) or fully depleted silicon on insulator (FDSOI), the fourth terminal is the back gate terminal of the transistor. In another embodiment in which the transistor comprises two gate terminals, the fourth terminal is one of the two gate terminals.

Since the active device 10 of FIG. 1 comprises a crossed coupled pair of transistors T1 and T2, the gate terminal G1 of the transistor T1 is connected to the drain terminal D2 of the transistor T2 and vice-versa.

In the embodiment of FIG. 1, the source terminals S1 and S2 are connected together and grounded.

In the embodiment of FIG. 1, the transistors T1 and T2 are N-type transistors. However, the invention is not limited to the use of N-type transistors and applies also to P-type transistors.

In the embodiment of FIG. 1, the fourth terminals B1 and B2 are connected together and set to a voltage VBG which can be controlled or modified by a control circuit (not illustrated). Although the connection of the fourth terminals of the active circuit 10 according to the invention allow a simplified control of their voltage, this feature is not essential and the fourth terminals of the active circuit 10 could be controlled separately, without the need to connect them together.

According to the invention, the control circuit (not illustrated) is arranged to modify the voltage at the fourth terminal B1, B2, so as to minimize a phase difference between a differential voltage of the oscillator carrier V and a device current i_{D} of the active circuit 10, the device current i_{D} of the active circuit 10 being a drain current flowing in one of the transistors T1, T2, thereby minimizing low frequency noise to phase noise conversion.

In this context, the expression “drain current” designates the differential current i_{D} flowing at the drain terminal of the corresponding transistor T1, T2. In this context, the drain current i_{D} is a signal current. In this context, the drain current is a differential current. Since the transistors T1, T2 form a crossed couple pair, the drain current i_{D} flowing at the drain terminal of the transistor T1 corresponds to the current i_{D} flowing at the drain terminal of the transistor T2.

In other words, by properly setting the voltage at the fourth terminals B1, B2, it is possible to minimize low-frequency noise to phase noise conversion even if the tank common-mode impedance at the oscillator second harmonic Z_{CMi}(2ω₀) is not optimally predicted.

In fact, the applicant has discovered that, it is possible to modify the value of the second-order transconductance g₂ in formula (5), by modifying the voltage at the fourth terminal of at least a sub-set of those transistors. This allows to reduce φ to small values or to a null value, thereby reducing the conversion of low-frequency noise to phase noise.

Advantageously, the modification of the value of the second-order transconductance g₂ does not change the amplitude of the generated differential voltage oscillator carrier. On the contrary, the modification of the value of the first-order transconductance g₁ or of the value of the third-order transconductance g₃ affects the amplitude of the generated differential voltage oscillator carrier.

Therefore, according to the invention it is possible to reduce φ to small values or to a null value, thereby reducing the conversion of low-frequency noise to phase noise, without affecting the amplitude of the generated differential voltage oscillator carrier.

Most importantly, this control can be performed even post fabrication, without modifying the hardware of the oscillator according to the invention. In fact, this modification can be implemented by an algorithm executed by the control circuit of the oscillator according to the invention.

In one embodiment, the transistors T1, T2 of the active circuit, is (are) realised in the technology fully depleted silicon on insulator (FDSOI) or in the technology deeply depleted channel (DDC).

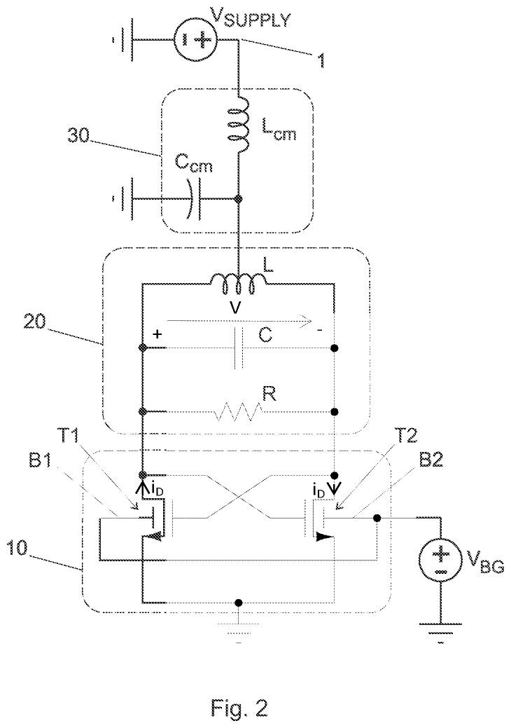

FIG. 2 illustrates schematically an oscillator 100 according to another embodiment of the invention. The only difference between the oscillator of FIG. 1 and the oscillator of FIG. 2 is that the oscillator of FIG. 2 is a voltage-biased oscillator.

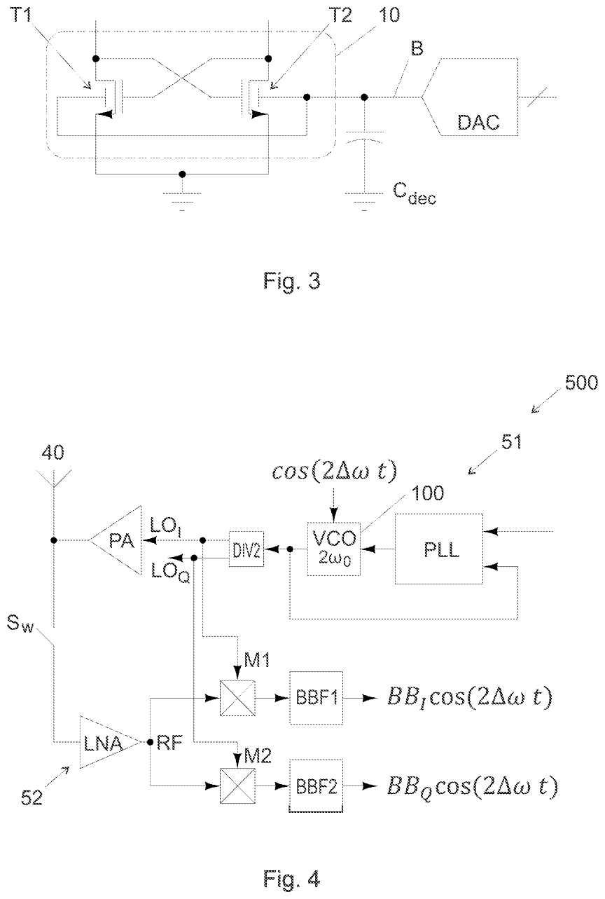

FIG. 3 illustrates schematically a portion of the oscillator according to another embodiment of the invention. In this embodiment, the control circuit comprises a digital to analog converter DAC whose output is connected to each fourth terminal B of the transistors of the active circuit 10, and a decoupling capacitor C_{dec} between the DAC's output and ground. This embodiment allows to carefully control the voltage at each fourth terminal of at least the sub-set of the transistors of the active circuit, by shunting the extra-noise to ground thanks to the decoupling capacitor, thereby avoiding affecting the working of the transistors.

In the embodiment of FIG. 3, the fourth terminals of the transistors of the active circuit 10 are connected together. Again, although the connection of the fourth terminals of the active circuit 10 according to the invention allow a simplified control of their voltage, this feature is not essential and the fourth terminals of the active circuit 10 could be controlled separately, e.g. with a single DAC (as in FIG. 3) or via multiple DACs, e.g. one for each fourth terminal. However, those last embodiments are less used, for the (high) number of their components.

FIG. 4 illustrates schematically a transceiver 500 comprising:
a transmitting path 51, comprising the oscillator 100 according to the invention, and
a receiving path 52.

In one preferred embodiment, the transceiver 500 is a radio-frequency (RF) transceiver.

In one embodiment, the transceiver comprises a single (RF) antenna port 40 common to transmitting path 51 and the receiving path 52.

In the embodiment of FIG. 4, the transmitting path 51 comprises:
a phase-locked loop PLL, the oscillator 100 being connected to the output of the phase-locked loop PLL, the output of the oscillator 100 being an input of the phase-locked loop PLL,
a divider DIV2, arranged to divide the frequency of the differential voltage oscillator carrier by a number, and being connected to the output of the oscillator 100,
a power amplifier PA, connected to an output of the divider DIV2.

In the embodiment of FIG. 4, the divider DIV2 is arranged to output two signals LO_{I} and LO_{Q}, the two signals being in quadrature.

In the embodiment of FIG. 4, the receiving path 52 comprises:
a low noise amplifier LNA,
two mixers M1, M2, each mixer being connected to the output of the low noise amplifier LNA, one of the mixer M1 being connected to a first output of the divider LO_{I}, and the other mixer M2 being connected to a second output of the divider LO_{Q},
an analog and/or digital base-band circuit, comprising base-band filters BBF1, BBF2, each base-band filter being connected to an output of each mixer.

In the embodiment of FIG. 4, the transceiver 500 comprises also a switch Sw connecting the output of the power amplifier PA to the input of the low noise amplifier LNA.

The transceiver 500 of FIG. 4 comprises also a transceiver control circuit (not illustrated), arranged to:
close said switch, thereby creating a loopback path between the transmitting path 51 and the receiving path 52,
inject a low-frequency tone (in the example, cos (2Δωt)), thereby generating up-converted tones around the differential voltage oscillator carrier.

Aw indicates a frequency much lower than the carrier frequency, e.g. a frequency lower than 100 MHZ, in particular between 10 Hz and 100 MHz.

In the embodiment of FIG. 4, the divider DIV2 is arranged to divide by two. However, this number should not be considered as limitative. In one embodiment, if the low-frequency tone is cos (NΔωt)), then the divider DIV2 is arranged to divide the input by N, N being an integer positive number.

The differential voltage oscillator carrier becomes after the DIV2

$${LO}_{I} = A cos ( {ω}_{o} t ) \pm α cos [ ( {ω}_{o} \pm Δ ω ) t + ψ ] \qquad ( 6 )$$

$${LO}_{Q} = - A sin ( {ω}_{o} t ) ∓ α sin [ ( {ω}_{o} \pm Δ ω ) t + ψ ] \qquad ( 7 )$$

wherein α is the amplitude of the up-converted tones.

The signal at the LNA output (via the loopback path, i.e., when the switch Sw is closed) becomes:

$$AF = A cos ( {ω}_{o} t + φ ) \pm α cos [ ( {ω}_{o} \pm Δ ω ) t + ψ + φ ] \qquad ( 8 )$$

wherein
φ is the phase shift between the PA output signal and the LNA input signal
ψ is the phase difference between the up-converted tones and the carrier.

Looking at the base-band at frequency 2Δω (or in general NΔω) it is possible to retrieve the following signals BB_{I} and BB_{Q}:

$${BB}_{I} = {α}^{2} cos ( φ ) \qquad ( 9 )$$

$$B {B}_{Q} = {α}^{2} sin ( φ ) \qquad ( 10 )$$

At the digital base-band circuits following the base-band filters BBF1 and BBF2, it is possible to process the signals BB_{I} and BB_{Q} e.g., according to the following formula:

$${BB}_{I}^{2} + {BB}_{Q}^{2} \qquad ( 11 )$$

in order to recover a without any dependency on p.

Calibration can thus be done by minimizing a while sweeping the voltage at the fourth terminal of the active circuit of the oscillator 100, so as to minimize the amplitude a of the up-converted tones, thereby calibrating the oscillator 100 to reduce the low-frequency to phase-noise conversion.

This calibration is performed at the start-up of the transceiver 500.

Advantageously, this calibration does not require any additional hardware for the transceiver 500, but it is performed by the transceiver control circuit.

### REFERENCE SIGNS USED IN THE FIGURES

1 Common node
10 Active circuit
20 Differential part of the circuit tank
30 Common mode part of the circuit tank
40 Antenna port
51 Transmitting path
52 Receiving path
100 Oscillator
500 Transceiver
B, B1, B2 Fourth terminal
BFF Base-band filter
C Capacitor
C_{big} (Big) capacitor
C_{cm} Common mode capacitor
C_{dec} Decoupling capacitor
D1, D2 Drain terminal
DAC Digital to Analog Converter
DIV Divider
G1, G2 Gate terminal
I_{bias} Bias current
L Inductor
L_{cm} Common mode inductor
LNA Low Noise Amplifier
M1, M2 Mixer
PA Power Amplifier
PLL Phase-locked loop
R Resistor
S1, S2 Source terminal
Sw Switch
T1, T2 Transistor
V_{BG} Fourth terminal-gate terminal tension
V_{SUPPLY} Supply tension
VCO Oscillator

1. An oscillator arranged to output a differential voltage oscillator carrier, the oscillator comprising:
a tank circuit,
an active circuit connected to the tank circuit, the active circuit comprising a crossed coupled pair of transistors, each transistor comprising a terminal, said terminal allowing to modify a threshold voltage of the transistor,
wherein the oscillator comprises a control circuit arranged to modify the voltage at the fourth terminal of at least a subset of said transistors, so as to minimize a phase difference between the differential voltage oscillator carrier and a device current of the active circuit, the device current of the active circuit being a drain current flowing in one of the transistors, thereby minimizing low frequency noise to phase noise conversion.

2. The oscillator of claim 1, wherein the control circuit is arranged to modify the voltage at the fourth terminal of all said transistors.

3. The oscillator of claim 1, wherein at least the sub-set of said transistors is realised in the technology fully depleted silicon on insulator or in the technology deeply depleted channel.

4. The oscillator of claim 3, wherein all said transistors are realised in the technology fully depleted silicon on insulator or in the technology deeply depleted channel.

5. The oscillator of claim 1, wherein the control circuit comprises at least one digital-to-analog converter whose output is connected to each fourth terminal of the sub-set of said transistors, and a decoupling capacitor between the DAC's output and a ground.

6. The oscillator of claim 1, the tank circuit comprising a common mode part and a differential part.

7. The oscillator of claim 6, wherein the common mode part is modeled as a common inductor between a supply node and a common node, and a common capacitor between the common node and the ground.

8. The oscillator of claim 6, wherein the differential part comprises an inductor, a capacitor and a resistor, the inductor, the capacitor and the resistor being in parallel.

9. The oscillator of claim 1, the oscillator being a voltage-biased oscillator.

10. The oscillator of claim 1, the oscillator being a current-biased oscillator.

11. A transceiver comprising:
a transmitting path, comprising:
the oscillator of claim 1,
a receiving path.

12. The transceiver of claim 11, comprising a single antenna port common to transmitting path and the receiving path.

13. The transceiver of claim 11, wherein
the transmitting path comprises:
a phase-locked loop, the oscillator being connected to an output of the phase-locked loop, an output of the oscillator being an input of the phase-locked loop,
a divider, arranged to divide the frequency of the oscillator carrier by a number, and being connected to the output of the oscillator,
a power amplifier, connected to an output of the divider, the receiving path comprises:
a low noise amplifier,
two mixers, each mixer being connected to the output of the low noise amplifier, one of the mixer being connected to a first output of the divider, and the other mixer being connected to a second output of the divider,
an analog and digital base-band circuit, connected to the output of the each mixer,
a switch connecting the output of the power amplifier to the input of the low noise amplifier,
a transceiver control circuit, arranged to perform the following steps:
close said switch, thereby creating a loopback path between the transmitting path and the receiving path,
inject a low-frequency tone at a supply of said oscillator, thereby generating up-converted tones around the differential voltage oscillator carrier,
recover at the digital base-band circuit the amplitude of the up-converted tones,
sweep the voltage at the fourth terminal of the active circuit transistors, so as to minimize the amplitude of the up-converted tones, thereby calibrating the oscillator to reduce the low-frequency to phase-noise conversion.

14. The transceiver of claim 13, wherein transceiver control circuit is arranged to perform said steps at a start-up phase of said transceiver.
